(19) United States
(12) Patent Application Publication
(10) Pub. No.: US 2024/0387483 A1
(43) Pub. Date: Nov. 21, 2024

(54) SEMICONDUCTOR PACKAGE

(71) Applicant: Samsung Electronics Co., Ltd., Suwon-si (KR)

(72) Inventors: Juhyeon Kim, Suwon-si (KR); Yeongseon Kim, Suwon-si (KR); Sunkyoung Seo, Suwon-si (KR)

(21) Appl. No.: 18/493,041

(22) Filed: Oct. 24, 2023

(30) Foreign Application Priority Data
May 15, 2023 (KR) 10-2023-0062390

(51) Int. Cl. H01L 25/10; H01L 23/00; H01L 23/31; H01L 23/48; H01L 23/498

(52) U.S. Cl. CPC H01L 25/105; H01L 23/3128; H01L 23/481; H01L 23/49822; H01L 24/06; H01L 24/08; H01L 2224/06181; H01L 2224/08145; H01L 2224/08225

(57) ABSTRACT

A semiconductor package may include a redistribution substrate, a first lower semiconductor chip on the redistribution substrate, an upper semiconductor chip on the first lower semiconductor chip, and a first insulating element between the redistribution substrate and the upper semiconductor chip to enclose the first lower semiconductor chip. The first lower semiconductor chip may include a first pad on a first surface of the first lower semiconductor chip, a first protection layer enclosing the first pad, a first penetration via that penetrates the first lower semiconductor chip and is electrically connected to the first pad, a second pad on a second surface of the first lower semiconductor chip facing the upper semiconductor chip, and a first insulating layer including the second pad. A particle size of a material including the first protection layer may be smaller than that of the first insulating element.

### CROSS-REFERENCE TO RELATED APPLICATIONS

This U.S. non-provisional patent application claims priority under 35 U.S.C. § 119 to Korean Patent Application No. 10-2023-0062390, filed on May 15, 2023, in the Korean Intellectual Property Office, the entire contents of which are hereby incorporated by reference.

### BACKGROUND

The present disclosure relates to a semiconductor package and a method of fabricating the same, and in particular, to a semiconductor package including a redistribution substrate and a method of fabricating the same.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps. As the electronics industry advances, various studies are being conducted to develop a highly reliable, highly integrated, and compact semiconductor package.

In light of recent advancements in the electronics industry, the demand for high-performance, high-speed, and compact electronic components has been steadily increasing. As a result, there is a development of packaging technologies that allow for the mounting of multiple semiconductor chips within a single package.

Recently, a demand for portable electronic devices has been rapidly increasing in the market, and thus, it is necessary to reduce sizes and weights of electronic components including in the portable electronic devices. For this, it is necessary to develop packaging technologies of reducing a size and a weight of each component and of integrating a plurality of individual components in a single package. In particular, to process high frequency signals, it may be necessary to reduce a size of a semiconductor package and improve its electrical characteristics.

### SUMMARY

Embodiments of the inventive concept provides a semiconductor package, which can be fabricated with improved process efficiency and high productivity, and a method of fabricating the same.

Some embodiments of the inventive concept provides a method of simplifying a process of fabricating a semiconductor package and reducing a failure rate in the fabrication process and a semiconductor package fabricated thereby.

According to some embodiments of the inventive concept, a semiconductor package may include a redistribution substrate, a first lower semiconductor chip on the redistribution substrate, an upper semiconductor chip on the first lower semiconductor chip, and a first insulating element between the redistribution substrate and the upper semiconductor chip. The first insulating element encloses the first lower semiconductor chip in a first plane that is parallel to the redistribution substrate. The first lower semiconductor chip may include a first pad on a first surface of the first lower semiconductor chip, a first protection layer that encloses the first pad in a second plane that is parallel to the redistribution substrate, a first penetration via that penetrates the first lower semiconductor chip and connected to the first pad, a second pad on a second surface of the first lower semiconductor chip facing the upper semiconductor chip, and a first insulating layer including the second pad. A particle size of a material including the first protection layer may be smaller than a particle size of a material including the first insulating element.

According to some embodiments of the inventive concept, a semiconductor package may include a first semiconductor chip, a second semiconductor chip on the first semiconductor chip, and an insulating element in a region, which is defined by a first surface of the first semiconductor chip. The insulating element encloses the second semiconductor chip in a first plane that is parallel to a surface of the first semiconductor chip. The second semiconductor chip may include a first pad on a first surface of the second semiconductor chip, a protection layer that encloses the first pad in a second plane that is parallel to a surface of the first semiconductor chip, a penetration via that penetrates the second semiconductor chip and is electrically connected to the first pad, a second pad on a second surface of the second semiconductor chip facing the first semiconductor chip, and an insulating layer that encloses the second pad in a third plane that is parallel to a surface of the first semiconductor chip. The insulating element may have a a height of a first surface of the insulating element that decreases with respect to the first semiconductor chip as a distance from the second semiconductor chip increases.

According to some embodiments of the inventive concept, a semiconductor package may include a redistribution substrate, a lower semiconductor chip on the redistribution substrate, an upper semiconductor chip on the lower semiconductor chip, and an insulating element between the redistribution substrate and the upper semiconductor chip. The insulating element encloses the lower semiconductor chip in a first plane that is parallel to the redistribution substrate. The lower semiconductor chip may include a first pad at a bottom surface of the lower semiconductor chip, a protection layer that encloses the first pad in a second plane that is parallel to the redistribution substrate, a penetration via that penetrates the lower semiconductor chip and is electrically connected to the first pad, a second pad on a first surface of the upper semiconductor chip facing the lower semiconductor chip, and an insulating layer that encloses the second pad in a third plane that is parallel to the redistribution substrate.

The upper semiconductor chip may include a third pad on first surface of the upper semiconductor chip facing the lower semiconductor chip, and an insulating layer that encloses the third pad in a fourth plane that is parallel to the redistribution substrate. The insulating element may include an epoxy molding compound (EMC). The second pad and the third pad may be in direct contact with each other, at an interface where the lower semiconductor chip and the upper semiconductor chip are in contact with each other, and may include a same material to form a single element.

### BRIEF DESCRIPTION OF THE DRAWINGS

FIGS. 1 and 2 are sectional views illustrating a semiconductor package, according to some embodiments of the inventive concept.

FIGS. 3, 4, 5, 6, 7, 8, 9, 10, 11, 13, 14, and 15 are sectional views illustrating a method of fabricating a semiconductor package, according to some embodiments of the inventive concept.

FIG. 12 is an enlarged sectional view illustrating a portion ‘A’ of FIG. 11.

### DETAILED DESCRIPTION

Example embodiments of the inventive concepts will now be described more fully with reference to the accompanying drawings, in which example embodiments are shown.

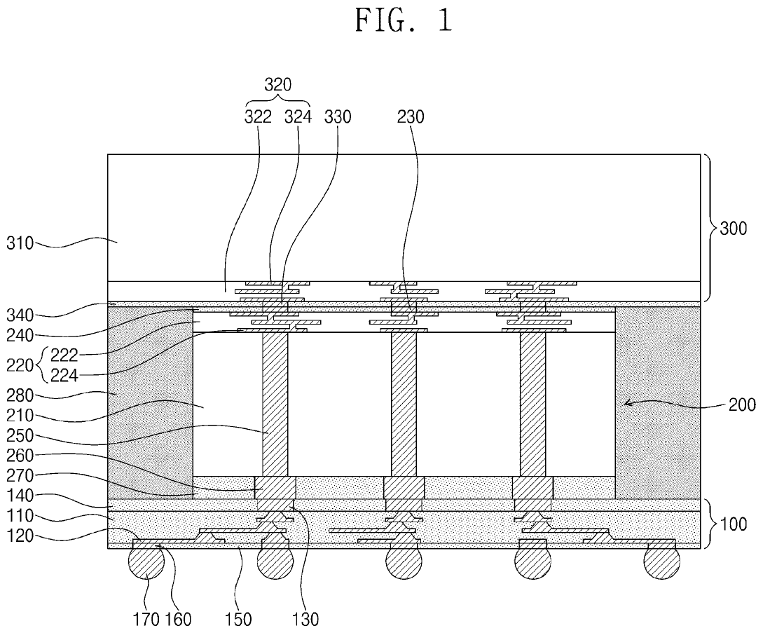

FIG. 1 is a sectional view illustrating a semiconductor package according to some embodiments of the inventive concept.

Referring to FIG. 1, a redistribution substrate 100 may be provided. The redistribution substrate 100 may be a substrate which is configured to allow for redistribution of a device (e.g., a first lower semiconductor chip 200) mounted thereon. The redistribution substrate 100 may include a first insulating pattern 110 and interconnection patterns 120, which are provided in the first insulating pattern 110.

The first insulating pattern 110 may be formed of or include at least one insulating polymer and/or photoimageable dielectric (PID) material. For example, the PID materials may be formed of or include at least one of photoimageable polyimide, polybenzoxazole (PBO), phenol-based polymers, or benzocyclobutene-based polymers. In some embodiments, the first insulating pattern 110 may include an insulating material. For example, the first insulating pattern 110 may be formed of or include at least one of silicon oxide (SiO), silicon nitride (SiN), silicon oxynitride (SiON), or insulating polymers.

The interconnection patterns 120 may be provided in the first insulating pattern 110. The interconnection patterns 120 may be horizontally extended in the first insulating pattern 110. Adjacent ones of the interconnection patterns 120 may be electrically connected to each other, in the first insulating pattern 110. Some of the interconnection patterns 120 may be exposed to the outside of the first insulating pattern 110 near a top surface of the first insulating pattern 110 and may be connected to a redistribution substrate pad 130, which will be described below. The interconnection patterns 120 may be formed of or include at least one conductive material. For example, the interconnection patterns 120 may be formed of or include at least one metallic material (e.g., copper (Cu)).

The interconnection patterns 120 may have a damascene structure. For example, the interconnection pattern 120 may include a head portion, which is extended in a horizontal direction, and a via portion, which is provided on the head portion. The head portion may be an element for horizontal interconnection in the redistribution substrate 100. The via portion may be an element for vertical interconnection in the redistribution substrate 100. The via portion may be a protruding portion that is extended from a top surface of the head portion. The via portion of the interconnection pattern 120 may be extended in an upward direction and may be coupled to a bottom surface of another interconnection pattern 120 thereon. The interconnection pattern 120 may have an inverted shape of letter ‘T’.

Although not shown, a barrier layer may be interposed between the first insulating pattern 110 and the interconnection pattern 120. The barrier layer may be provided to enclose the head portion and the via portion of the interconnection pattern 120. A thickness of the barrier layer may range from 50 Å to 1000 Å. The barrier layer may be formed of or include at least one of titanium (Ti), tantalum (Ta), titanium nitride (TiN), or tantalum nitride (TaN).

For convenience in description, FIG. 1 illustrates an example, in which the interconnection patterns 120 are provided in one first insulating pattern 110, but the first insulating pattern 110 may include a plurality of stacked insulating layers. Here, one of the insulating layers and some interconnection patterns 120 therein may include a single interconnection layer, and the redistribution substrate 100 may have a multi-layered structure, in which a plurality of interconnection layers are stacked. The following description will be given based on the example embodiment of FIG. 1.

The redistribution substrate pad 130 may be provided on the top surface of the first insulating pattern 110. The redistribution substrate pad 130 may be electrically connected to the interconnection pattern 120. For example, portions of the interconnection pattern 120, which are exposed near the top surface of the first insulating pattern 110, may be provided to penetrate the first insulating pattern 110 and may be coupled to the redistribution substrate pads 130. In more detail, the via portion of such an interconnection pattern 120 may be exposed to the outside of the first insulating pattern 110 near the top surface of the first insulating pattern 110 and may be coupled to the redistribution substrate pad 130. The redistribution substrate pad 130 may be formed of or include at least one conductive material. For example, the redistribution substrate pad 130 may be formed of or include at least one metallic material (e.g., copper (Cu)). In some embodiments, a plurality of redistribution substrate pads 130 may be provided.

A first insulating layer 140 may be provided on the redistribution substrate 100. The first insulating layer 140 may enclose the redistribution substrate pad 130. The first insulating layer 140 may be provided to cover or overlap the top surface of the first insulating pattern 110 and expose the redistribution substrate pad 130. The first insulating layer 140 may be used as a protection layer for protecting the first insulating pattern 110 and the interconnection pattern 120. The first insulating layer 140 may include an insulating material. For example, the first insulating layer 140 may be formed of or include at least one of silicon nitride (SiN), silicon oxide (SiO), silicon oxynitride (SiON), or tetraethyl orthosilicate (TEOS).

A substrate protection layer 150 may be provided below the first insulating pattern 110. The substrate protection layer 150 may be provided to cover, overlap, or be on a bottom surface of the first insulating pattern 110 and expose an outer pad 160, which will be described below. The substrate protection layer 150 may be formed of or include at least one of insulating polymers or photoimageable dielectric (PID) materials.

The outer pads 160 may be provided on the bottom surface of the first insulating pattern 110. The outer pads 160 may be electrically connected to the interconnection patterns 120. At least one of the interconnection patterns 120, which is exposed to the outside of the first insulating pattern 110 near the bottom surface of the first insulating pattern 110, may be coupled to the outer pad 160. In more detail, the head portion of such an interconnection pattern 120 may be exposed to the outside of the first insulating pattern 110 near the bottom surface of the first insulating pattern 110 and may be in contact with the outer pad 160. The outer pad 160 may be used as a pad for connection with an outer terminal 170, which will be described below. The outer pad 160 may be formed of or include at least one conductive material. For example, the outer pad 160 may be formed of or include at least one metallic material (e.g., copper (Cu)). In some embodiments, a plurality of outer pads 160 may be provided.

The outer terminal 170 may be provided on a bottom surface of the outer pad 160. The outer terminals 170 may include solder balls or solder bumps. Depending on the kind or arrangement of the outer terminals 170, the semiconductor package may be provided in the form of a ball-grid array (BGA) structure, a fine ball-grid array (FBGA) structure, or a land grid array (LGA) structure. In some embodiments, a plurality of outer terminals 170 may be provided.

The redistribution substrate 100 may be provided to have the afore-described structure. However, the inventive concept is not limited to this example. The redistribution substrate 100 may be a printed circuit board (PCB). For example, the redistribution substrate 100 may include a core layer and peripheral portions, which are disposed on and under the core layer and are used as an interconnection structure.

The first lower semiconductor chip 200 may be provided on the redistribution substrate 100. The first lower semiconductor chip 200 may be disposed on a center region of the redistribution substrate 100. A bottom surface of the first lower semiconductor chip 200 may be in direct contact with top surface of the redistribution substrate 100. The first lower semiconductor chip 200 may be one of memory chips, such as DRAM, SRAM, MRAM and FLASH memory chips.

The first lower semiconductor chip 200 may have a front surface and a rear surface. Hereinafter, in the present specification, the front surface may be a surface of a semiconductor chip, which is called an active surface, and on which integrated devices or pads are formed, and the rear surface may be another surface of the semiconductor chip that is opposite to the front surface. The first lower semiconductor chip 200 may be disposed on the redistribution substrate 100 in a face-up manner. In detail, the rear surface of the first lower semiconductor chip 200 may face the redistribution substrate 100. That is, the bottom surface of the first lower semiconductor chip 200 may be the rear surface of the first lower semiconductor chip 200, and the top surface of the first lower semiconductor chip 200 may be the front surface of the first lower semiconductor chip 200. The first lower semiconductor chip 200 may include a first lower semiconductor substrate 210, a first circuit layer 220 provided on a top surface of the first lower semiconductor substrate 210, and a first penetration via 250 vertically penetrating the first lower semiconductor substrate 210.

The first lower semiconductor substrate 210 may be a semiconductor substrate. For example, the first lower semiconductor substrate 210 may be formed of or include silicon (Si). An integrated device or integrated circuits may be formed on a top surface of the first lower semiconductor substrate 210.

The first circuit layer 220 may be provided on the top surface of the first lower semiconductor substrate 210. The first circuit layer 220 may be electrically connected to the integrated device or circuits, which are formed on the top surface of the first lower semiconductor substrate 210. For example, the first circuit layer 220 may include a second insulating pattern 222 and a first circuit pattern 224, which is provided in the second insulating pattern 222. The second insulating pattern 222 may be provided to cover or overlap the integrated device or circuits, on the top surface of the first lower semiconductor substrate 210. The first circuit pattern 224 may be coupled to the integrated device or circuits, which are formed on the first lower semiconductor substrate 210.

A first pad 230 may be provided on a top surface of the first circuit layer 220. The first pad 230 may be electrically connected to the first circuit pattern 224 of the first circuit layer 220. For example, the first pad 230 may be in contact with a portion of the first circuit pattern 224, which is exposed near a top surface of the second insulating pattern 222. The first pad 230 may include at least one conductive material. For example, the first pad 230 may be formed of or include at least one metallic material (e.g., copper (Cu)). In some embodiments, a plurality of first pads 230 may be provided.

A second insulating layer 240 may be provided on the top surface of the first circuit layer 220 to enclose the first pad 230. The second insulating layer 240 may cover or overlap the top surface of the first circuit layer 220 and expose the first pad 230. A top surface of the second insulating layer 240 and a top surface of the first pad 230 may be substantially flat and may be substantially coplanar with each other. The second insulating layer 240 may include an insulating material. For example, the second insulating layer 240 may be formed of or include at least one of silicon nitride (SiN), silicon oxide (SiO), silicon oxynitride (SiON), or tetraethyl orthosilicate (TEOS).

The first penetration via 250 may be provided to vertically penetrate the first lower semiconductor substrate 210. The first penetration via 250 may extend toward the top surface of the first lower semiconductor chip 200 and may be connected to the first circuit layer 220 or the integrated device or circuits, which are formed on the first lower semiconductor substrate 210. In some embodiments, the first penetration via 250 may be coupled to the first circuit pattern 224 of the first circuit layer 220. The first penetration via 250 may extend toward the bottom surface of the first lower semiconductor chip 200 and may be connected to a second pad 260, which will be described below. In some embodiments, a plurality of first penetration vias 250 may be provided.

The second pad 260 may be provided on the bottom surface of the first lower semiconductor chip 200. The second pad 260 may be electrically connected to the first penetration via 250. The second pad 260 may be formed of or include at least one conductive material. For example, the second pad 260 may be formed of or include at least one metallic material (e.g., copper (Cu)). In some embodiments, a plurality of second pads 260 may be provided.

A first protection layer 270 may be provided on a bottom surface of the first lower semiconductor substrate 210 to enclose the second pad 260. The first protection layer 270 may cover or overlap the bottom surface of the first lower semiconductor substrate 210 and expose the second pad 260. Since the bottom surface of the first lower semiconductor chip 200 (i.e., the bottom surface of the first protection layer 270) is in contact with the redistribution substrate 100, the second pad 260 of the first lower semiconductor chip 200 may be in contact with the redistribution substrate pad 130 of the redistribution substrate 100. Thus, the first lower semiconductor chip 200 may be electrically connected to the redistribution substrate 100.

An upper semiconductor chip 300 may be disposed on the first lower semiconductor chip 200. A width of the upper semiconductor chip 300 may be larger than a width of the first lower semiconductor chip 200. When viewed in a plan view, the first lower semiconductor chip 200 may be placed inside the upper semiconductor chip 300. The upper semiconductor chip 300 may be a logic chip. In some embodiments, the upper semiconductor chip 300 may be one of memory chips, such as DRAM, SRAM, MRAM and FLASH memory chips.

The upper semiconductor chip 300 may have a front surface and a rear surface. The front surface of the upper semiconductor chip 300 may face the first lower semiconductor chip 200. For example, the upper semiconductor chip 300 may be disposed on the first lower semiconductor chip 200 in a face-down manner. In other words, the upper semiconductor chip 300 and the first lower semiconductor chip 200 may be bonded to each other in a face-to-face manner. The upper semiconductor chip 300 may include an upper semiconductor substrate 310 and a second circuit layer 320, which is provided on a bottom surface of the upper semiconductor substrate 310.

The upper semiconductor substrate 310 may be a semiconductor substrate. In some embodiments, the upper semiconductor substrate 310 may be formed of or include silicon (Si). An integrated device or integrated circuits may be formed on the bottom surface of the upper semiconductor substrate 310.

The second circuit layer 320 may be provided on the bottom surface of the upper semiconductor substrate 310. The second circuit layer 320 may be electrically connected to the integrated device or circuits, which are formed on the bottom surface of the upper semiconductor substrate 310. For example, the second circuit layer 320 may include a third insulating pattern 322 and a second circuit pattern 324, which is provided in the third insulating pattern 322. The third insulating pattern 322 may be provided to cover or overlap the integrated device or circuits, on the bottom surface of the upper semiconductor substrate 310. The second circuit pattern 324 may be coupled to the integrated device or circuits, which are formed on the upper semiconductor substrate 310.

A third pad 330 may be provided on a bottom surface of the second circuit layer 320. The third pad 330 may be electrically connected to the second circuit pattern 324 of the second circuit layer 320. For example, the third pad 330 may be in contact with a portion of the second circuit pattern 324, which is exposed near a bottom surface of the third insulating pattern 322. The third pad 330 may be formed of or include at least one conductive material. For example, the third pad 330 may be formed of or include at least one metallic material (e.g., copper (Cu)). In some embodiments, a plurality of third pads 330 may be provided.

A third insulating layer 340 may be provided on the bottom surface of the second circuit layer 320 to enclose the third pad 330 in a plane parallel to the redistribution substrate. The third insulating layer 340 may be provided to cover or overlap the bottom surface of the second circuit layer 320 and expose the third pad 330. A bottom surface of the third insulating layer 340 and a bottom surface of the third pad 330 may be substantially flat and may be substantially coplanar with each other. The third insulating layer 340 may include an insulating material. For example, the third insulating layer 340 may be formed of or include at least one of silicon nitride (SiN), silicon oxide (SiO), silicon oxynitride (SiON), or tetraethyl orthosilicate (TEOS).

The upper semiconductor chip 300 may be mounted on the first lower semiconductor chip 200. For example, a bottom surface of the upper semiconductor chip 300 may face the top surface of the first lower semiconductor chip 200. The upper semiconductor chip 300 and the first lower semiconductor chip 200 may be bonded to each other. In more detail, the second circuit layer 320 of the upper semiconductor chip 300 may be in contact with the first circuit layer 220 of the first lower semiconductor chip 200. Here, since the width of the first lower semiconductor chip 200 is smaller than the width of the upper semiconductor chip 300, an edge portion of the bottom surface of the upper semiconductor chip 300 may not be covered or overlapped with the first lower semiconductor chip 200 and may be exposed to the outside. The third pad 330 of the upper semiconductor chip 300 may be vertically aligned to the first pad 230 of the first lower semiconductor chip 200. At an interface between the upper semiconductor chip 300 and the first lower semiconductor chip 200, the third pad 330 of the upper semiconductor chip 300 may be in direct contact with the first pad 230 of the first lower semiconductor chip 200. Here, the first and third pads 230 and 330 may form an inter-metal hybrid bonding structure. In the present specification, the hybrid bonding structure may refer to a bonding structure which is formed by two materials, which are of the same kind and are fused at an interface therebetween. For example, the first and third pads 230 and 330, which are bonded to each other, may have a continuous structure, and there may be no visible or observable interface between the first and third pads 230 and 330. For example, the first and third pads 230 and 330 may be formed of the same material, and thus, there may be no visible or observable interface between the first and third pads 230 and 330. In other words, the first and third pads 230 and 330 may be provided as a single object or element. For example, the first and third pads 230 and 330 may be bonded to each other to form a single object. However, the inventive concept is not limited to this example. In some embodiments, the first and third pads 230 and 330 may be provided as distinct elements, and in this case, there may be a visible or observable interface between the first and third pads 230 and 330. The upper semiconductor chip 300 may be electrically connected to the first lower semiconductor chip 200 through the third pad 330.

A first insulating element 280 may be provided on the redistribution substrate 100. The first insulating element 280 may be disposed beside or around the first lower semiconductor chip 200. The first insulating element 280 may be placed between the redistribution substrate 100 and the upper semiconductor chip 300. The first insulating element 280 may enclose the first lower semiconductor chip 200, when viewed in a plan view. The first insulating element 280 may fully or partially enclose the first lower semiconductor chip 200 when viewed in plan view, or in a plane that is parallel to the redistribution substrate 100 between the upper semiconductor chip 300 and the redistribution substrate 100. The first insulating element 280 may be in contact with side surfaces of the first lower semiconductor chip 200.

When viewed in a plan view, a side surface of the first insulating element 280 may be aligned to a side surface of the upper semiconductor chip 300 and a side surface of the redistribution substrate 100. For example, a width of the first insulating element 280 may be equal to the width of the upper semiconductor chip 300 and the width of the redistribution substrate 100. Here, the width of the first insulating element 280 may refer to a distance between outer side surfaces of the first insulating element 280, which are opposite to each other. In detail, the width of the first lower semiconductor chip 200 may be smaller than the width of the upper semiconductor chip 300, and the first insulating element 280 may enclose the first lower semiconductor chip 200 within a region defined by the bottom surface of the upper semiconductor chip 300.

The first insulating element 280 may be formed of or include a material that is different from the first protection layer 270 of the first lower semiconductor chip 200. For example, a material including the first protection layer 270 may have a different particle size from that of a material including the first insulating element 280. In the present specification, the term “particle size” may be defined as a diameter or other dimension of a basic constituent part (an atom or molecule) of a target material, which is measured when a sampled part of the target material is inspected with a scanning electron microscope (SEM) or a transmission electron microscope (TEM), and here, the basic constituent part of the target material is presumed to have an ideal spherical shape. A first particle size of the first protection layer 270 may range from 10 nm to 200 nm, and a second particle size of the first insulating element 280 may range from 10 μm to 75 μm. That is, the second particle size may be 50 to 7500 times the first particle size. The first protection layer 270 may include an insulating material. For example, the first protection layer 270 may be formed of or include at least one of silicon nitride (SiN), silicon oxide (SiO), silicon oxynitride (SiON), or tetraethyl orthosilicate (TEOS), and the first insulating element 280 may be formed of or include an epoxy molding compound (EMC).

A top surface of the first insulating element 280 may have a concave shape that becomes more lowered as a distance from an interface between the first protection layer 270 and the first insulating element 280 increases. That is, a distance from the top surface of the first insulating element 280 to the redistribution substrate 100 decreases as the distance from the interface between the first protection layer 270 and the first insulating element 280 increases. Other features of the semiconductor package will be described in more detail with reference to a fabrication method to be described below.

According to some embodiments of the inventive concept, the first protection layer 270 and the first insulating element 280 may be formed of or include different materials from each other. Since the particle size of the material of the first insulating element 280 is smaller than the particle size of the material of the first protection layer 270, the first protection layer 270 may be used as a stop layer in a planarization process. Thus, it may be possible to process the first insulating element 280 more easily in the fabrication process of the semiconductor package. This will be described in more detail with reference to a fabrication process to be described below.

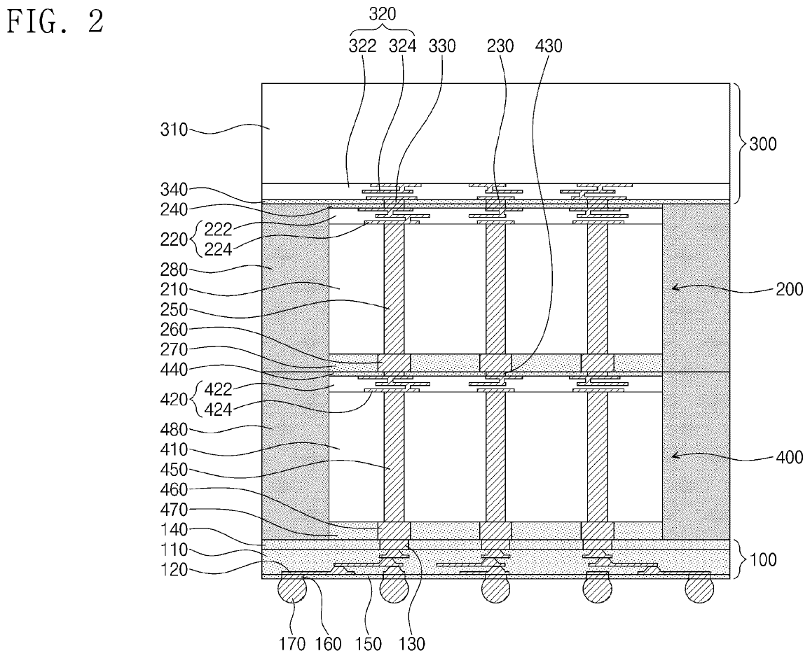

FIG. 2 is a sectional view illustrating a semiconductor package according to some embodiments of the inventive concept. In the description of the embodiments to be explained below, an element previously described with reference to FIG. 1 may be identified by the same reference number without repeating an overlapping description thereof, for concise description.

Referring to FIG. 2, a semiconductor package may further include a second lower semiconductor chip 400 and a second insulating element 480.

The second lower semiconductor chip 400 may be provided on the redistribution substrate 100. The second lower semiconductor chip 400 may be between the redistribution substrate 100 and the first lower semiconductor chip 200. The second lower semiconductor chip 400 may be disposed on the center region of the redistribution substrate 100. The second lower semiconductor chip 400 may be provided to have a structure that is the same as or similar to the first lower semiconductor chip 200. A bottom surface of the second lower semiconductor chip 400 may be in direct contact with the top surface of the redistribution substrate 100.

The second lower semiconductor chip 400 may have a front surface and a rear surface. The second lower semiconductor chip 400 may be disposed on the redistribution substrate 100 in a face-up manner. In more detail, the rear surface of the second lower semiconductor chip 400 may face the redistribution substrate 100. The front surface of the second lower semiconductor chip 400 may face the first lower semiconductor chip 200. In other words, the bottom surface of the second lower semiconductor chip 400 may be the rear surface of the second lower semiconductor chip 400, and the top surface of the second lower semiconductor chip 400 may be the front surface of the second lower semiconductor chip 400. In other words, the second lower semiconductor chip 400 may be disposed on or bonded to the rear surface of the first lower semiconductor chip 200 in a face-to-back manner. The second lower semiconductor chip 400 may include a second lower semiconductor substrate 410, a third circuit layer 420 provided on a top surface of the second lower semiconductor substrate 410, and a second penetration via 450 vertically penetrating the second lower semiconductor substrate 410.

The second lower semiconductor substrate 410 may be a semiconductor substrate. As an example, the second lower semiconductor substrate 410 may be formed of or include silicon (Si). An integrated device or integrated circuits may be formed on the top surface of the second lower semiconductor substrate 410.

The third circuit layer 420 may be provided on the top surface of the second lower semiconductor substrate 410. The third circuit layer 420 may be electrically connected to the integrated device or circuits, which are formed on the top surface of the second lower semiconductor substrate 410. For example, the third circuit layer 420 may include a fourth insulating pattern 422 and a third circuit pattern 424, which is provided in the fourth insulating pattern 422. The fourth insulating pattern 422 may be provided on the top surface of the second lower semiconductor substrate 410 to cover the integrated device or circuits. The third circuit pattern 424 may be coupled to the integrated device or circuits, which are formed on the second lower semiconductor substrate 410.

A fourth pad 430 may be provided on a top surface of the third circuit layer 420. The fourth pad 430 may be electrically connected to the third circuit pattern 424 of the third circuit layer 420. For example, the fourth pad 430 may be in contact with a portion of the third circuit pattern 424 which is exposed to the outside near a top surface of the fourth insulating pattern 422. The fourth pad 430 may be formed of or include at least one conductive material. For example, the fourth pad 430 may be formed of or include at least one metallic material (e.g., copper (Cu)). In some embodiments, a plurality of fourth pads 430 may be provided.

A fourth insulating layer 440 may be provided on the top surface of the third circuit layer 420 to enclose the fourth pad 430. The fourth insulating layer 440 may be provided to cover or overlap the top surface of the third circuit layer 420 and expose the fourth pad 430. A top surface of the fourth insulating layer 440 and a top surface of the fourth pad 430 may be substantially flat and may be substantially coplanar with each other. The fourth insulating layer 440 may include an insulating material. For example, the fourth insulating layer 440 may be formed of or include at least one of silicon nitride (SiN), silicon oxide (SiO), silicon oxynitride (SiON), or tetraethyl orthosilicate (TEOS).

The second penetration via 450 may be provided to vertically penetrate the second lower semiconductor substrate 410. The second penetration via 450 may be extended toward the top surface of the second lower semiconductor chip 400 and may be connected to the third circuit layer 420 or the integrated device or circuits, which are formed on the second lower semiconductor substrate 410. In some embodiments, the second penetration via 450 may be coupled to the third circuit pattern 424 of the third circuit layer 420. The second penetration via 450 may be extended toward the bottom surface of the second lower semiconductor chip 400 and may be connected to a fifth pad 460, which will be described below. In some embodiments, a plurality of second penetration vias 450 may be provided.

The fifth pad 460 may be provided on the bottom surface of the second lower semiconductor chip 400. The fifth pad 460 may be electrically connected to the second penetration via 450. The fifth pad 460 may be formed of or include at least one conductive material. For example, the fifth pad 460 may include at least one metallic material (e.g., copper (Cu)). In some embodiments, a plurality of fifth pads 460 may be provided.

A second protection layer 470 may be provided on a bottom surface of the second lower semiconductor substrate 410 to enclose the fifth pad 460. The second protection layer 470 may cover or overlap the bottom surface of the second lower semiconductor substrate 410 and expose the fifth pad 460. Since the bottom surface of the first lower semiconductor chip 200 (i.e., the bottom surface of the first protection layer 270) is in contact with the redistribution substrate 100, the second pad 260 of the first lower semiconductor chip 200 may be in direct contact with the redistribution substrate pad 130 of the redistribution substrate 100. Thus, the second lower semiconductor chip 400 may be electrically connected to the redistribution substrate 100.

The first lower semiconductor chip 200 may be mounted on the second lower semiconductor chip 400. For example, the first lower semiconductor chip 200 may be provided to have a bottom surface facing the top surface of the second lower semiconductor chip 400. When viewed in a plan view, the first lower semiconductor chip 200 and the second lower semiconductor chip 400 may be provided to have outer side surfaces that are aligned to or coplanar with each other. The first lower semiconductor chip 200 may be in contact with the second lower semiconductor chip 400. The second pad 260 of the first lower semiconductor chip 200 may be vertically aligned to the fourth pad 430 of the second lower semiconductor chip 400. Here, the second and fourth pads 260 and 430 may form an inter-metal hybrid bonding structure. For example, the second and fourth pads 260 and 430, which are bonded to each other, may have a continuous structure, and there may be no visible or observable interface between the second and fourth pads 260 and 430. The first lower semiconductor chip 200 may be electrically connected to the second lower semiconductor chip 400 through the second pad 260.

The second insulating element 480 may be provided on the redistribution substrate 100. The second insulating element 480 may be disposed beside or around the second lower semiconductor chip 400. The second insulating element 480 may be placed between the redistribution substrate 100 and the first insulating element 280 to enclose the second lower semiconductor chip 400. The second insulating element 480 may be in contact with side surfaces of the second lower semiconductor chip 400.

When viewed in a plan view, a side surface of the second insulating element 480 may be aligned to the side surface of the upper semiconductor chip 300, the side surface of the first insulating element 280, and the side surface of the redistribution substrate 100. For example, a width of the second insulating element 480 may be equal to the width of the upper semiconductor chip 300, the width of the first insulating element 280, and the width of the redistribution substrate 100. In detail, a width of the second lower semiconductor chip 400 may be smaller than the width of the upper semiconductor chip 300, and the second insulating element 480 may enclose the second lower semiconductor chip 400 within a region defined by the bottom surface of the upper semiconductor chip 300. A top surface of the second insulating element 480 may be coplanar with the top surface of the second lower semiconductor chip 400. In other words, an interface between the first and second insulating elements 280 and 480 may be located at the same level as an interface between the first and second lower semiconductor chips 200 and 400.

The second protection layer 470 and the second insulating element 480 may be formed of or include different materials from each other. For example, a material including the second protection layer 470 may have a different particle size from that of the second insulating element 480. In detail, a third particle size of the second protection layer 470 may range from 10 nm to 200 nm, and a fourth particle size of the second insulating element 480 may range from 10 μm to 75 μm. In other words, the third particle size may be 50 to 7500 times the fourth particle size. The second protection layer 470 may include an insulating material. For example, the second protection layer 470 may be formed of or include at least one of silicon nitride (SiN), silicon oxide (SiO), silicon oxynitride (SiON), or tetraethyl orthosilicate (TEOS), and the second insulating element 480 may be formed of or include an epoxy molding compound (EMC).

According to some embodiments of the inventive concept, since the material of the second insulating element 480 has a particle size that is larger than that of the material of the second protection layer 470, the second protection layer 470 may be used as a stop layer in a planarization process (e.g., a grinding process). Thus, the second insulating element 480 may be more easily processed in the fabrication process of the semiconductor package.

The semiconductor package may be provided to have the afore-described structure.

FIG. 2 illustrates an example, in which two lower semiconductor chips and two insulating elements are provided between the upper semiconductor chip 300 and the redistribution substrate 100, but the inventive concept is not limited to this example. Two or more lower semiconductor chips and insulating elements, which are formed to enclose the lower semiconductor chips, respectively, may be provided between the upper semiconductor chip 300 and the redistribution substrate 100. Here, the disposition of the lower semiconductor chips, the interconnection between the lower semiconductor chips, and the disposition of the insulating elements may be substantially the same as or similar to those of the first and second lower semiconductor chips 200 and 400 and the first and second insulating elements 280 and 480 described with reference to FIG. 2.

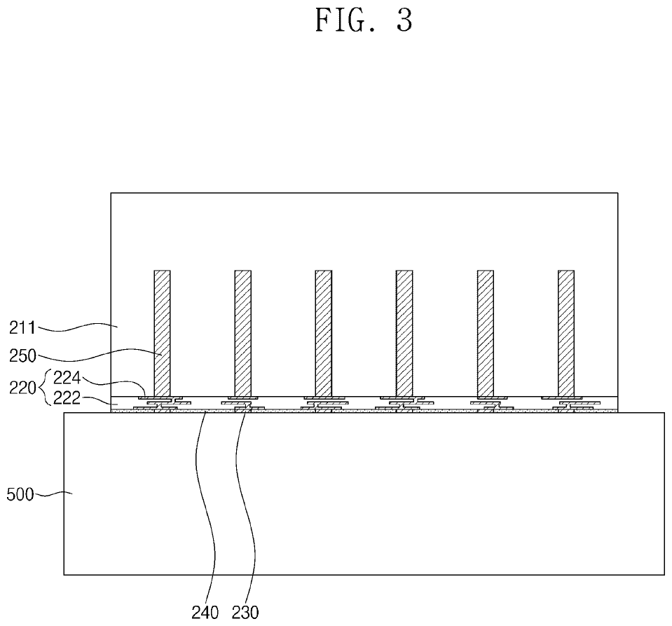

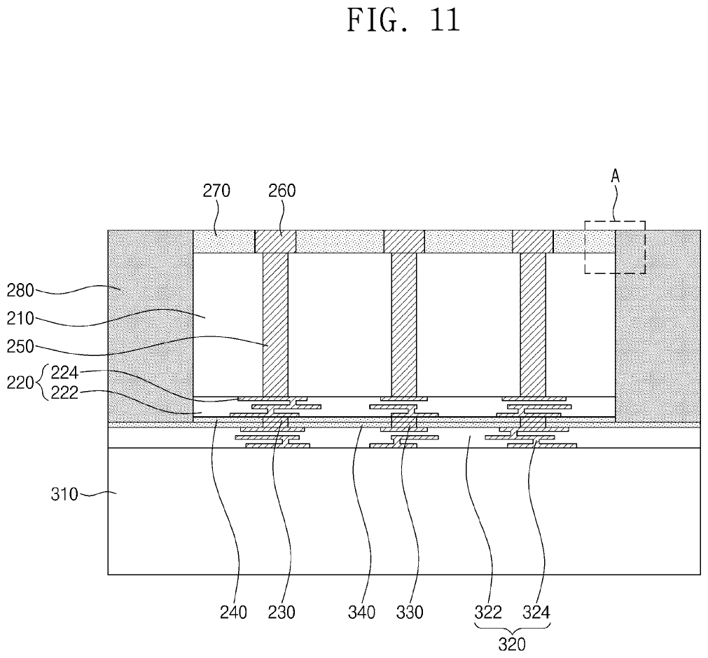

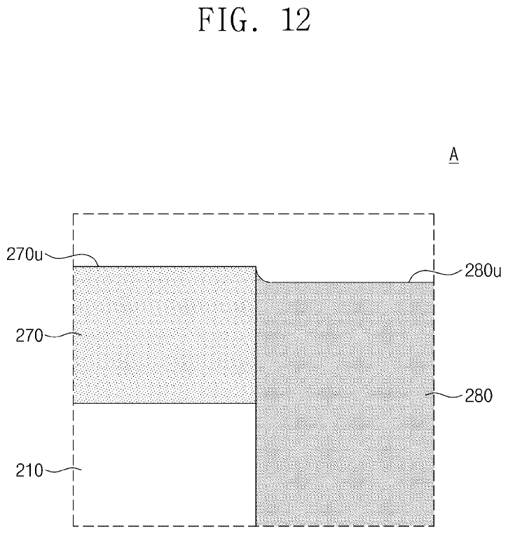

FIGS. 3 to 11 and 13 to 15 are sectional views illustrating a method of fabricating a semiconductor package, according to some embodiments of the inventive concept. FIG. 12 is an enlarged sectional view illustrating a portion ‘A’ of FIG. 11.

The first lower semiconductor chip 200 may be fabricated. The fabrication method of the first lower semiconductor chip 200 will be described in more detail with reference to FIGS. 3 to 8.

A carrier substrate 500 may be provided. The carrier substrate 500 may be an insulating substrate, which is formed of or includes glass or polymer, or a conductive substrate, which is formed of or includes a metallic material. Although not shown, an adhesive member may be provided on a top surface of the carrier substrate 500. As an example, the adhesive member may include an adhesive tape.

Referring to FIG. 3, a semiconductor wafer 211 may be provided. The first lower semiconductor chips 200 may be fabricated by performing a conventional process on the semiconductor wafer 211. In more detail, integrated circuits (e.g., transistors) may be formed on a bottom surface of the semiconductor wafer 211. The first penetration vias 250 may be formed by forming penetration holes to penetrate the semiconductor wafer 211 and partially or fully filling the penetration holes with a conductive material. Here, the penetration holes may be extended from the bottom surface of the semiconductor wafer 211 toward a top surface of the semiconductor wafer 211 and may not fully penetrate the semiconductor wafer 211. Thus, the first penetration via 250 may not be exposed to the outside through the top surface of the semiconductor wafer 211. The second insulating pattern 222 may be formed by depositing an insulating material on the bottom surface of the semiconductor wafer 211 and patterning the insulating material. The first circuit pattern 224 may be formed by forming a conductive material on the second insulating pattern 222 and patterning the conductive material. The second insulating pattern 222 and the first circuit pattern 224, which are formed by the afore-described process, may include the first circuit layer 220. The second insulating layer 240 may be formed by depositing an insulating material on the first circuit layer 220. The formation of the first pad 230 may include patterning the second insulating layer 240 to form a trench exposing the first circuit pattern 224 and filling the trench with a conductive material.

The semiconductor wafer 211 may be attached to the carrier substrate 500. For example, the semiconductor wafer 211 may be disposed on the carrier substrate 500 such that the bottom surface of the semiconductor wafer 211 faces the carrier substrate 500. That is, the second insulating layer 240 and the first pad 230 may be attached to the top surface of the carrier substrate 500. Here, since a width of the semiconductor wafer 211 is smaller than a width of the carrier substrate 500, an edge portion of the top surface of the carrier substrate 500 may not be covered or overlapped with the semiconductor wafer 211, and may be exposed to the outside.

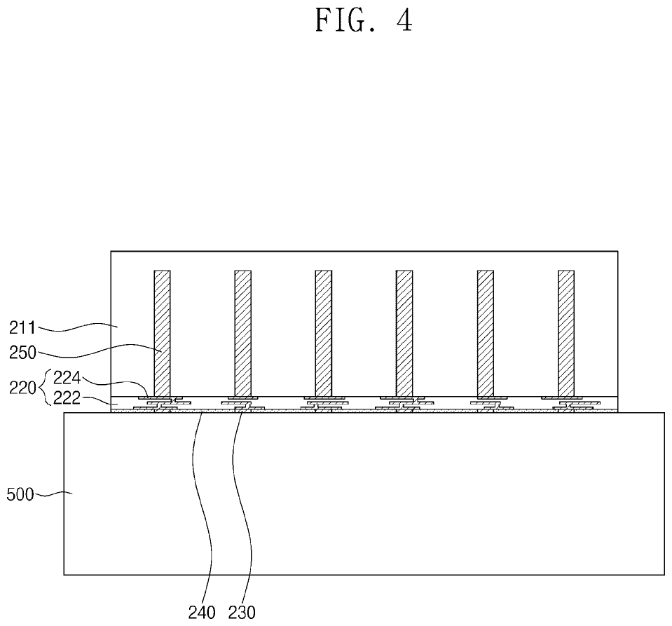

Referring to FIG. 4, a portion of the semiconductor wafer 211 may be removed. In more detail, a back-grinding process may be performed on the top surface of the semiconductor wafer 211. An upper portion of the semiconductor wafer 211 may be removed during the back-grinding process. As a result of the back-grinding process, the top surface of the semiconductor wafer 211 may be lowered to a level that is close to a top surface of the first penetration via 250. The back-grinding process may be finished before the first penetration via 250 is exposed to the outside. That is, the first penetration via 250 may not be polished.

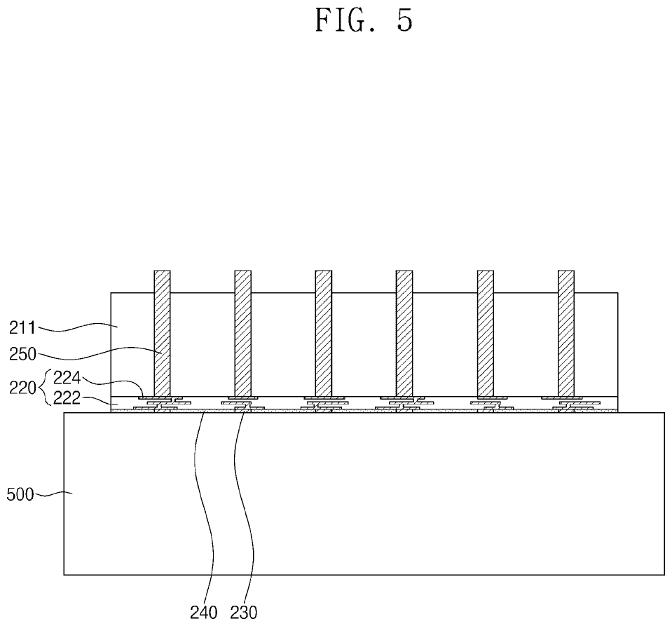

Referring to FIG. 5, a portion of the semiconductor wafer 211 may be removed. In more detail, an etching process may be performed on the top surface of the semiconductor wafer 211. In detail, a wet or dry etching process may be performed. The etching process may be performed to selectively etch the semiconductor wafer 211, but not the first penetration via 250. After the etching process, the first penetration via 250 may be exposed to the outside of the semiconductor wafer 211 and may have a top surface that is located at a level higher than the top surface of the semiconductor wafer 211. That is, after the etching process, the first penetration via 250 may have a protruding portion that is higher than the top surface of the semiconductor wafer 211.

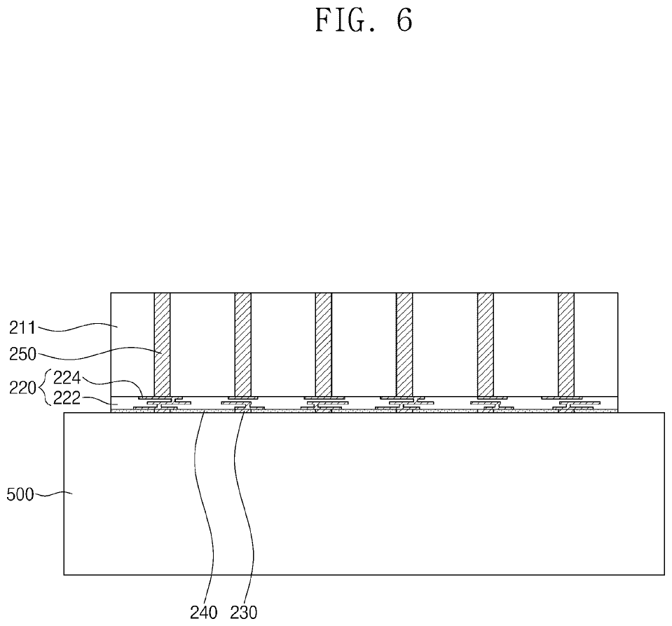

Referring to FIG. 6, a portion of the semiconductor wafer 211 and a portion of the first penetration via 250 may be removed. A chemical mechanical polishing (CMP) process may be performed on the semiconductor wafer 211 and the top surface of the first penetration via 250. The top surface of the semiconductor wafer 211 and the top surface of the first penetration via 250 may be substantially flat and may be substantially coplanar with each other.

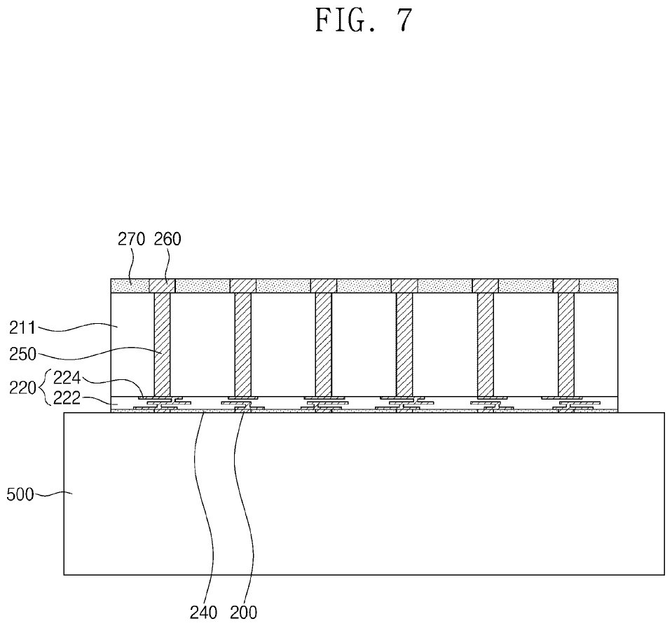

Referring to FIG. 7, the second pad 260 and the first protection layer 270 may be formed on the top surface of the semiconductor wafer 211, and here, the first protection layer 270 may be formed to enclose the second pad 260. For example, the first protection layer 270 may be formed by depositing a photoimageable insulating layer on the semiconductor wafer 211. Openings may be formed by performing a patterning process on the first protection layer 270. The second pads 260 may be formed by filling the openings of the first protection layer 270 with a conductive material. The second pad 260 may be electrically connected to the first penetration via 250.

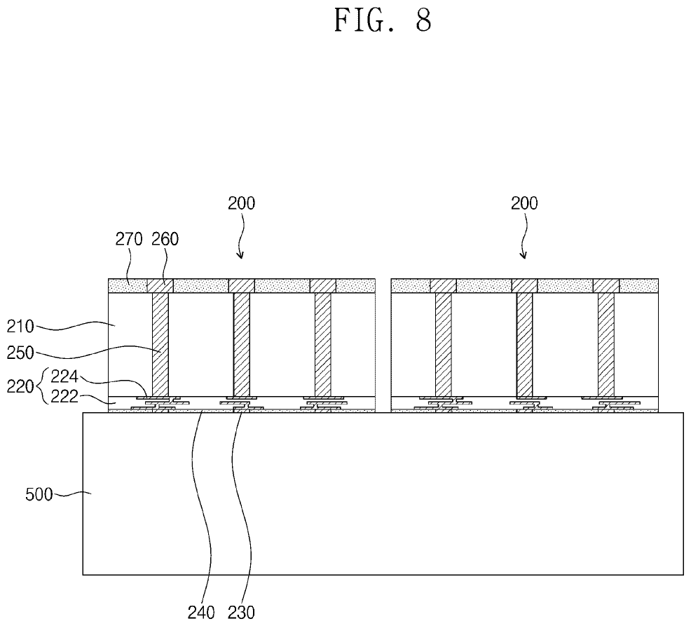

Referring to FIG. 8, a dicing process may be performed on the semiconductor wafer 211, the second insulating layer 240, and the first protection layer 270. For example, a blade dicing process, a laser dicing process, and/or a plasma dicing process may be performed. As a result of the dicing process, a plurality of first lower semiconductor chips 200 may be separated from each other.

The first lower semiconductor chip 200 may be fabricated through the afore-described process.

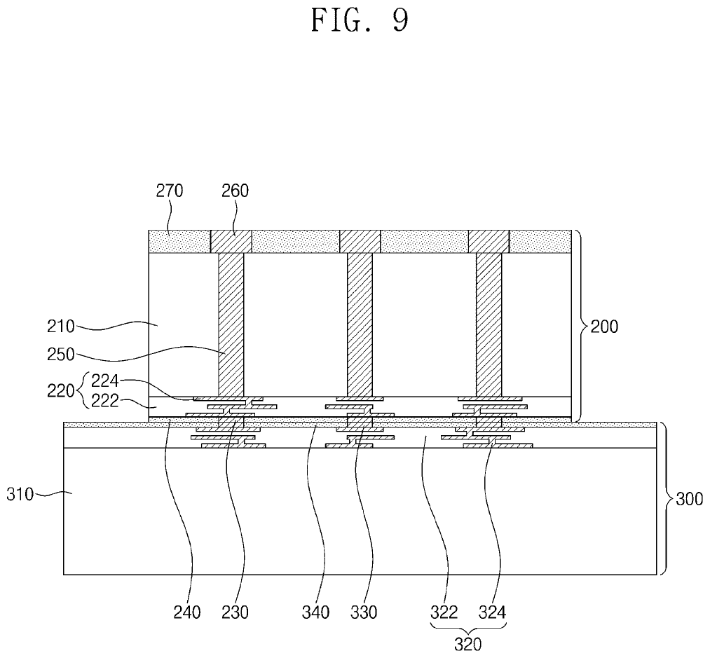

Referring to FIG. 9, the upper semiconductor chip 300 and the first lower semiconductor chip 200 may be provided. The first lower semiconductor chip 200 may be mounted on the upper semiconductor chip 300. For example, the second lower semiconductor chip 400 may be placed on the upper semiconductor chip 300 such that a bottom surface of the first lower semiconductor chip 200 faces the upper semiconductor chip 300. One of the first lower semiconductor chip 200 and the upper semiconductor chip 300 may be moved toward the other such that the first lower semiconductor chip 200 is in contact with the upper semiconductor chip 300. In some embodiments, the second circuit layer 320 of the upper semiconductor chip 300 may be in contact with the first circuit layer 220 of the first lower semiconductor chip 200. Here, since the width of the first lower semiconductor chip 200 is smaller than the width of the upper semiconductor chip 300, an edge portion of the bottom surface of the upper semiconductor chip 300 may not be covered or overlapped by the first lower semiconductor chip 200 and may be exposed to the outside. At the interface between the upper semiconductor chip 300 and the first lower semiconductor chip 200, the third pad 330 of the upper semiconductor chip 300 may be in direct contact with the first pad 230 of the first lower semiconductor chip 200.

The first lower semiconductor chip 200 and the upper semiconductor chip 300 may be bonded to each other. For example, the first pad 230 of the first lower semiconductor chip 200 may be bonded to the third pad 330 of the upper semiconductor chip 300 to form a single object. The bonding between the third pad 330 of the upper semiconductor chip 300 and the first pad 230 of the first lower semiconductor chip 200 may be performed in a natural manner. In detail, the first and third pads 230 and 330 may be formed of the same material (e.g., copper (Cu)), and in this case, the first circuit layer 220 of the first lower semiconductor chip 200 may be bonded to the second circuit layer 320 of the upper semiconductor chip 300 through an inter-metal hybrid bonding process (e.g., copper-copper hybrid bonding), which is caused by surface activation at an interface between the first and third pads 230 and 330. The upper semiconductor chip 300 may be electrically connected to the first lower semiconductor chip 200 through the third pad 330. In some embodiments, the first pad 230 of the first lower semiconductor chip 200 and the third pad 330 of the upper semiconductor chip 300 may be in direct contact with each other such that an interface is formed between the first lower semiconductor chip 200 and the upper semiconductor chip 300.

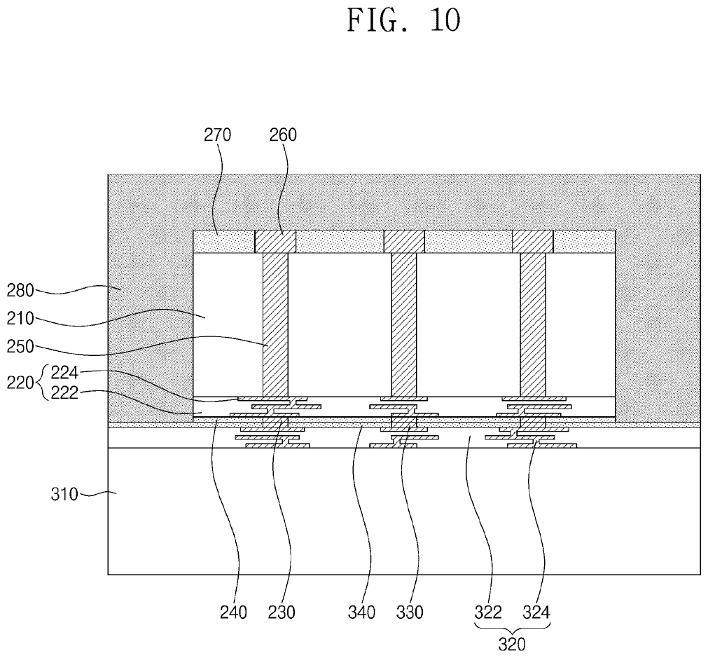

Referring to FIG. 10, the first insulating element 280 may be formed on the upper semiconductor chip 300. In more detail, the first insulating element 280 may be formed by coating a molding member on the upper semiconductor chip 300 to cover the first lower semiconductor chip 200 and curing the molding member. Thus, the first lower semiconductor chip 200 on the upper semiconductor chip 300 may be buried in the first insulating element 280.

When viewed in a plan view, the side surface of the first insulating element 280 may be aligned to the side surface of the upper semiconductor chip 300. For example, the first insulating element 280 may be formed such that the first insulating element 280 has the same width as the upper semiconductor chip 300. The first insulating element 280 may enclose the first lower semiconductor chip 200 within a region defined by the bottom surface of the upper semiconductor chip 300.

Referring to FIG. 11, a portion of the first insulating element 280 may be removed. In detail, a grinding or chemical mechanical polishing (CMP) process may be performed on the top surface of the first insulating element 280. The grinding or CMP process may be performed until the top surfaces of the second pad 260 and the first protection layer 270 are exposed to the outside. In the case where the grinding process is performed, a polishing rate of the first insulating element 280 may be higher than a polishing rate of the first protection layer 270, because the material of the first insulating element 280 has a particle size larger than the material of the first protection layer 270. Thus, the first protection layer 270 may not be polished by a grinding process. That is, the first protection layer 270 may serve as a stop layer. According to some embodiments of the inventive concept, the first insulating element 280 may be over-polished during the grinding process. Hereinafter, an interface between the first protection layer 270 and the first insulating element 280 will be described in more detail with reference to FIG. 12.

Referring to FIG. 12, a distance from a top surface 280u of the first insulating element 280 to the upper semiconductor chip 300 may decrease as a distance from the interface between the first protection layer 270 and the first insulating element 280 increases. In other words, the top surface 280u of the first insulating element 280 may have a concave shape that becomes more lowered as a distance from the interface between the first protection layer 270 and the first insulating element 280 increases. A height difference between the top surface 280u of the first insulating element 280 and a top surface 270u of the first protection layer 270 may range from 1 nm to 1 μm. Here, the height difference between the top surface 280u of the first insulating element 280 and the top surface 270u of the first protection layer 270 may mean a vertical level difference from the lowermost point of the top surface 280u of the first insulating element 280 to the top surface 270u of the first protection layer 270. At the interface between the first protection layer 270 and the first insulating element 280, the top surface 270u of the first protection layer 270 may be connected to the top surface 280u of the first insulating element 280. However, the inventive concept is not limited to this example. The top surface 280u of the first insulating element 280 and the top surface 270u of the first protection layer 270 may be substantially flat and may be substantially coplanar with each other. Hereinafter, a fabrication method according to some embodiments of the inventive concept will be described further.

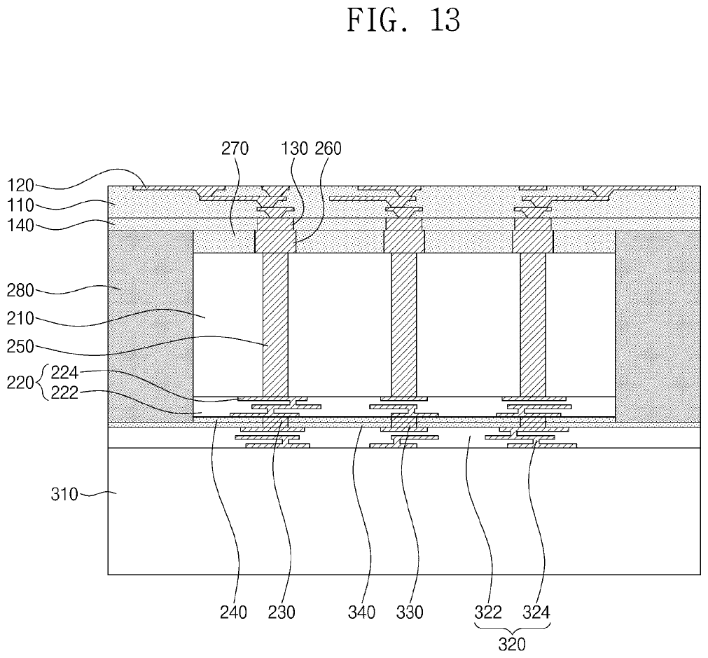

Referring to FIG. 13, the redistribution substrate 100 may be formed. For example, the first insulating layer 140 may be formed by depositing or coating an insulating material on the first lower semiconductor chip 200 and the first insulating element 280. Thereafter, the first insulating layer 140 may be patterned to form an opening exposing the second pad 260, and then, the redistribution substrate pad 130 may be formed by partially or fully filling the opening with a conductive material.

An insulating material may be deposited on the first insulating layer 140 to form an insulating layer, and then, the insulating layer may be patterned to form an opening exposing the redistribution substrate pad 130. A conductive layer may be formed on the insulating layer to cover or overlap the insulating layer and partially or fully fill the opening, and then, the conductive layer may be patterned to form the interconnection pattern 120. The insulating layer and the interconnection pattern 120 thereon may include a single interconnection layer, and in some embodiments, the first insulating pattern 110 and the first interconnection patterns 120 therein may be formed by repeating the process of forming the interconnection layer.

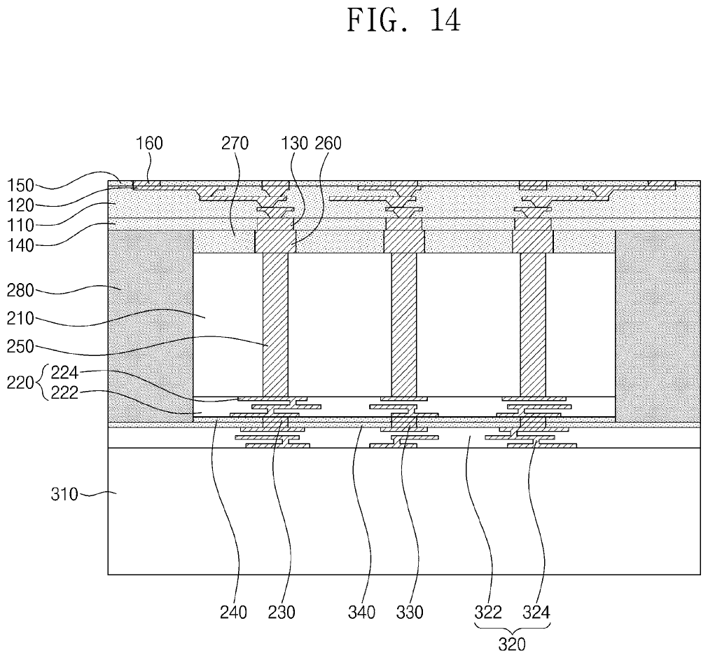

Referring to FIG. 14, the substrate protection layer 150 and the outer pad 160 may be formed on the top surface of the first insulating pattern 110. In detail, the substrate protection layer 150 may be formed by coating a photoimageable insulating layer on the first insulating pattern 110. An exposing process and a developing process may be performed on the substrate protection layer 150 to form penetration holes exposing the outer pads 160. The outer pads 160 may be formed by partially or fully filling the penetration holes of the substrate protection layer 150 with a conductive material. The photoimageable insulating layer may be formed of or include at least one of insulating polymers or photoimageable dielectric (PID) materials.

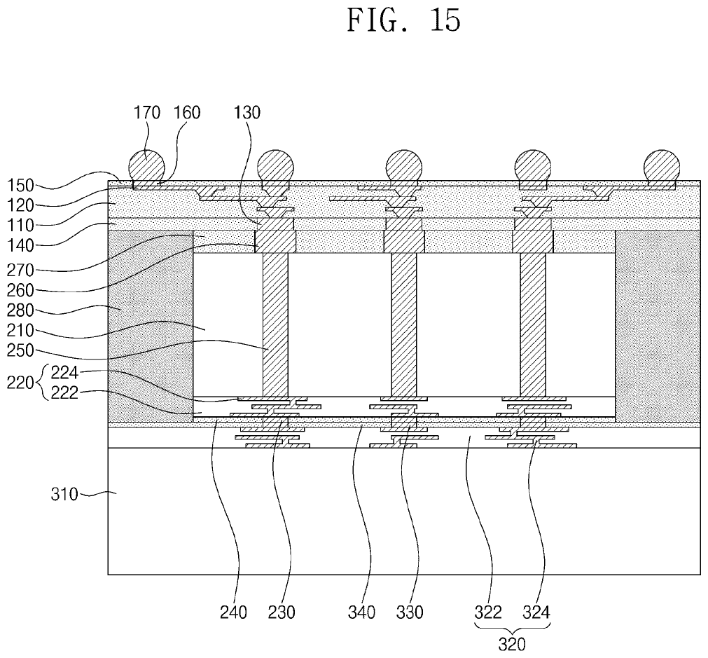

Referring to FIG. 15, the outer terminal 170 may be provided on an exposed top surface of the outer pad 160. For example, a connection terminal (e.g., a solder ball or a solder bump) may be attached to the outer pad 160. In some embodiments, a plurality of outer terminals 170 may be provided.

As a result of the afore-described fabrication process, the semiconductor package may be fabricated to have the structure of FIG. 1.

According to some embodiments of the inventive concept, a semiconductor package may be fabricated by performing a back-side process on a semiconductor chip in a wafer level and then performing a packaging process, and in this case, it may be possible to easily manage risk in a front-end step (e.g., forming penetration vias (e.g., through-silicon vias (TSVs))) of a chip fabrication process. Furthermore, a difference in heights between silicon and metal patterns can be reduced, compared with the conventional method of performing a back-side process in a chip level. Thus, the semiconductor package can be fabricated with improved process efficiency and/or high productivity.

According to some embodiments of the inventive concept, the semiconductor package may include a plurality of semiconductor chips, which have at least two different sizes and are electrically connected to each other, an insulating element, which is provided to partially or fully fill a space between the semiconductor chips, and a protection layer, which is provided on a top surface of the semiconductor chip and has a particle size different from that of the insulating element. In some embodiments, the protection layer may be formed of a material having a small particle size, and in this case, the protection layer may serve as a stop layer in a grinding process. As a result, it may be possible to simplify a fabrication process and improve the productivity and/or efficiency in the fabrication process.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a redistribution substrate;
a first lower semiconductor chip on the redistribution substrate;
an upper semiconductor chip on the first lower semiconductor chip; and
a first insulating element between the redistribution substrate and the upper semiconductor chip, wherein the first insulating element encloses the first lower semiconductor chip in a first plane that is parallel to the redistribution substrate,
wherein the first lower semiconductor chip comprises:
a first pad on a first surface of the first lower semiconductor chip;
a first protection layer that encloses the first pad in a second plane that is parallel to the redistribution substrate;
a first penetration via that penetrates the first lower semiconductor chip and is electrically connected to the first pad;
a second pad on a second surface of the first lower semiconductor chip facing the upper semiconductor chip; and
a first insulating layer including the second pad,
wherein a particle size of a material comprising the first protection layer is smaller than a particle size of a material comprising the first insulating element.

2. The semiconductor package of claim 1, wherein the upper semiconductor chip comprises:
a third pad on a first surface of the upper semiconductor chip facing the first lower semiconductor chip; and
a third insulating layer that encloses the third pad in a third plane that is parallel to the redistribution substrate,
wherein the second pad and the third pad are in direct contact with each other, at an interface where the first lower semiconductor chip and the upper semiconductor chip are in contact with each other, and comprise a same material to form a unitary structure.

3. The semiconductor package of claim 1, wherein the particle size of the material comprising the first insulating element is 50 to 7500 times the particle size of the material comprising the first protection layer.

4. The semiconductor package of claim 1, wherein a width of the first lower semiconductor chip is less than a width of the upper semiconductor chip.

5. The semiconductor package of claim 1, wherein the first protection layer comprises at least one of oxide, nitride, or tetraethyl orthosilicate (TEOS).

6. The semiconductor package of claim 1, wherein the first insulating element comprises an epoxy molding compound (EMC).

7. The semiconductor package of claim 1, wherein the first surface of the first lower semiconductor chip is in direct contact with a first surface of the redistribution substrate, and
wherein the first pad of the first lower semiconductor chip is in direct contact with a redistribution pad of the redistribution substrate.

8. The semiconductor package of claim 1, further comprising:
a second lower semiconductor chip between the redistribution substrate and the first lower semiconductor chip; and
a second insulating element that encloses the second lower semiconductor chip in a fourth plane that is parallel to the redistribution substrate,
wherein the second lower semiconductor chip comprises:
a fourth pad on a first surface of the second lower semiconductor chip;
a second protection layer that encloses the fourth pad in a fifth plane that is parallel to the redistribution substrate;
a second penetration via that penetrates the second lower semiconductor chip and is electrically connected to the fourth pad;
a fifth pad on a second surface of the second lower semiconductor chip facing the upper semiconductor chip; and
a second insulating layer including the fifth pad,
wherein a particle size of a material comprising the second protection layer is smaller than a particle size of a material comprising the second insulating element.

9. The semiconductor package of claim 8, wherein a width of the second lower semiconductor chip is less than a width of the upper semiconductor chip.

10. The semiconductor package of claim 8, wherein the first surface of the second lower semiconductor chip is in contact with a first surface of the redistribution substrate, and
wherein the fourth pad of the second lower semiconductor chip is in direct contact with a redistribution pad of the redistribution substrate.

11. A semiconductor package, comprising:
a first semiconductor chip;
a second semiconductor chip on the first semiconductor chip; and
an insulating element in a region which is defined by a first surface of the first semiconductor chip, wherein the insulating element encloses the second semiconductor chip in a first plane that is parallel to a surface of the first semiconductor chip,
wherein the second semiconductor chip comprises:
a first pad on a first surface of the second semiconductor chip;
a protection layer that encloses the first pad in a second plane that is parallel to the surface the first semiconductor chip;
a penetration via that penetrates the second semiconductor chip and is electrically connected to the first pad;
a second pad on a second surface of the second semiconductor chip facing the first semiconductor chip; and
an insulating layer that encloses the second pad in a third plane that is parallel to the surface of the first semiconductor chip,
wherein a height of a first surface of the insulating element with respect to the first semiconductor chip decreases as a distance from the second semiconductor chip increases.

12. The semiconductor package of claim 11, wherein the first surface of the insulating element and a first surface of the protection layer are in direct contact each other at an interface therebetween.

13. The semiconductor package of claim 11, wherein the height of the first surface of the insulating element is different from a height of a first surface of the protection layer by 1 nm to 1 μm with respect to the first semiconductor chip.

14. The semiconductor package of claim 11, wherein a width of the first semiconductor chip is greater than a width of the second semiconductor chip.

15. The semiconductor package of claim 11, wherein the protection layer comprises at least one of oxide, nitride, or tetraethyl orthosilicate (TEOS).

16. The semiconductor package of claim 11, wherein the insulating element comprises an epoxy molding compound (EMC).

17. A semiconductor package, comprising:
a redistribution substrate;
a lower semiconductor chip on the redistribution substrate;
an upper semiconductor chip on the lower semiconductor chip; and
an insulating element between the redistribution substrate and the upper semiconductor chip, wherein the insulating element encloses the lower semiconductor chip in a first plane that is parallel to the redistribution substrate,
wherein the lower semiconductor chip comprises:
a first pad at a bottom surface of the lower semiconductor chip;
a protection layer that encloses the first pad in a second plane that is parallel to the redistribution substrate;
a penetration via that penetrates the lower semiconductor chip and is electrically connected to the first pad;
a second pad on a first surface of the upper semiconductor chip facing the lower semiconductor chip; and
an lower insulating layer that encloses the second pad in a third plane that is parallel to the redistribution substrate,
wherein the upper semiconductor chip comprises:
a third pad on first surface of the upper semiconductor chip facing the lower semiconductor chip; and
an upper insulating layer that encloses the third pad in a fourth plane that is parallel to the redistribution substrate,
wherein the insulating element comprises an epoxy molding compound (EMC), and
wherein the second pad and the third pad are in direct contact with each other at an interface where the lower semiconductor chip and the upper semiconductor chip are in contact with each other, and comprise a same material to form a unitary structure.

18. The semiconductor package of claim 17, wherein a width of the lower semiconductor chip is less than a width of the upper semiconductor chip.

19. The semiconductor package of claim 17, wherein the protection layer comprises at least one of oxide, nitride, or tetraethyl orthosilicate (TEOS).

20. The semiconductor package of claim 17, wherein the bottom surface of the lower semiconductor chip is in direct contact with a first surface of the redistribution substrate, and
wherein the first pad of the lower semiconductor chip is in direct contact with a redistribution pad of the redistribution substrate.
